(19) United States
(12) Patent Application Publication
(10) Pub. No.: US 2022/0121119 A1
(43) Pub. Date: Apr. 21, 2022

(54) INFRARED RADIATION SENSITIVE POSITIVE-WORKING IMAGEABLE ELEMENT AND METHOD FOR FORMING IMAGE USING SAME

(71) Applicant: ZHEJIANG KONITA NEW MATERIALS CO., LTD., Wenzhou (CN)

(72) Inventors: Yinqiao WENG, Wenzhou (CN); Ting TAO, Wenzhou (CN); Miao GAO, Wenzhou (CN); Nengping XU, Wenzhou (CN); Zuoting YING, Wenzhou (CN); Xianyao MA, Wenzhou (CN); Leze JIAO, Wenzhou (CN)

(73) Assignee: ZHEJIANG KONITA NEW MATERIALS CO., LTD., Wenzhou (CN)

(21) Appl. No.: 17/432,809

(22) PCT Filed: Jan. 22, 2021
(86) PCT No.: PCT/CN2021/073386

§ 371 Date: Aug. 20, 2021

(30) Foreign Application Priority Data
Dec. 31, 2019 (CN) 201911408294.0

(51) Int. Cl. G03F 7/039; G03F 7/11; G03F 7/32; G03F 7/20

(52) U.S. Cl. CPC G03F 7/0392; G03F 7/11; B41C 1/10; G03F 7/2006; G03F 7/322

(57) ABSTRACT

Disclosed is a infrared radiation sensitive positive-working imageable element. The imageable element comprises: (a) a substrate, (b) an inner coating covering the substrate, and (c) an outer coating covering the inner coating. The inner coating comprises a repeating unit derived from a maleimide monomer and a (meth)acrylamide monomer, and a polymer hinder P that is soluble in an alkaline developing solution; and the outer coating comprises an infrared radiation absorbing compound and a polymer binder Q which is different from that in the inner coating. The imageable element is designed such that same is not only sensitive to radiation with a maximum wavelength of 700-1200 nm, but also has a good resistance to chemical solvents when used as a lithographic printing plate precursor, and same is not easily corroded and dissolved by printing chemicals during use, thus facilitating the prolonging of the service life of a lithographic printing plate.

### TECHNICAL FIELD

The present invention relates to an infrared radiation sensitive material and a positive-working imageable element made of the material and with improved chemical resistance. The present invention specifically relates to an infrared radiation sensitive positive-working lithographic printing plate precursor in the printing field, and a method for obtaining a lithographic printing plate using the precursor.

### BACKGROUND

The imageable element used to prepare a lithographic printing plate generally comprises one or more imageable layers applied on a hydrophilic surface (or an intermediate layer) of a carrier, and the imageable layer comprises one or more radiation sensitive components dispersed in a binder. After radiation imaging, the exposed or non-exposed area of the imageable layer is removed by a suitable developer, thus exposing the hydrophilic surface of the carrier underneath. If the exposed area is removed, the imageable element is considered to be positive-working. Conversely, if the non-exposed area is removed, the imageable element is considered to be negative-working. In either case, the unremoved areas of the imageable layer are ink-receptive, while the hydrophilic surface exposed by the development process accepts water or an aqueous solution (usually a fountain solution) and repels ink.

The radiation sensitive component of the imageable element used in the positive-working in the prior art is usually an imageable composition comprising novolak or other phenolic polymer binder and a diazoquinone imaging component. In addition, there are imageable compositions based on various phenolic resins and infrared radiation absorbing compounds. In actual lithographic printing, common printing room chemicals, such as printing plate cleaners, transfer cloth detergents, and alcohol substitutes in fountain solutions, especially a rinsing agent with high content of esters, ethers or ketones used in printing methods using UV curable inks, have corrosive effects on imageable compositions. Therefore, in order to ensure normal printing of the UV curable ink, the radiation sensitive composition used in the imageable composition must have good corrosion resistance.

However, both the quinonediazide compound and phenolic resin radiation sensitive composition commonly used in the prior art are soluble in glycol ether solvents for cleaning printing plates, which is not conducive to the printing of UV curable inks. Therefore, how to improve the resistance of the imageable composition to solvents and printing room chemicals has become an urgent technical problem in this field.

### SUMMARY OF THE INVENTION

The main technical problem to be solved by the present invention is to overcome the defect that the existing materials used for positive-working imageable elements are easily eroded by chemicals, and then provide an infrared radiation-sensitive imageable element with good resistance to alcohol-containing chemicals and a lithographic printing plate precursor prepared by using the material.

The technical solution of the present invention to solve the above technical problem is as follows:

An infrared radiation sensitive positive-working imageable element, which comprises:
(a) a substrate;
(b) an inner coating covering the substrate, the inner coating comprises a polymer binder P, which is derived from a repeating unit of a maleimide monomer and a (meth)acrylamide monomer and is soluble in an alkaline developing solution; and
(c) an outer coating covering the inner coating, the outer coating comprises an infrared radiation absorbing compound and a polymer binder Q which is different from the inner coating.

The polymer binder P comprised in the inner coating can be represented by the following structural formula (I):

—(A)x-(B)y-(C)z— (I)
A represents a repeating unit derived from one or more maleimide monomers

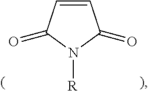

wherein R can be optionally substituted or unsubstituted alkyl, substituted or unsubstituted cycloalkyl, substituted or unsubstituted aryl, substituted or unsubstituted heteroaryl, hydroxyl, substituted or unsubstituted alkoxy; B represents a repeating unit derived from one or more (meth)acrylamide monomers

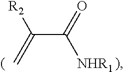

wherein R1 can be optionally hydrogen, substituted or unsubstituted alkyl, substituted or unsubstituted cycloalkyl, substituted or unsubstituted aryl, substituted or unsubstituted heteroaryl, hydroxyl, substituted or unsubstituted alkoxy; R₂ can be optionally hydrogen or methyl; C represents a repeating unit derived from one or more other ethylenically unsaturated polymerizable monomers different from A and B; wherein, based on x+y+z=100% of a total weight of the polymer binder P having a structural formula (I), optionally x is 1 to 85 wt %, y is 1 to 80 wt %, and z is 1 to 80 wt % or any combination thereof; and the polymer binder P is 40-99.9wt % of the total weight of the inner coating

Optionally, the inner coating further comprises a background contrast dye, and the background contrast dye is a dye with high absorption in the visible light region, preferably, the background contrast dye is selected from one or a mixture of an oil-soluble dye and/or a basic dye. The addition amount background contrast dye is added in an amount of 0.1 to 8 wt % of the total weight of the inner coating.

Optionally, the inner coating further comprises an infrared radiation absorbing compound having a wavelength absorption range of 700 to 1200 nm, preferably, the infrared radiation absorbing compound is one or more of a cyanine dye, an anthraquinone dye, a phthalocyanine dye, a quinonimine dye or a methine cyanine dye. The addition amount of the infrared radiation absorbing compound is 0.1 to 10 wt % of the total weight of the inner coating.

Optionally, the inner coating further comprises an acid generator, and the acid generator is one or more of onium salt, triazine, acid anhydride and sulfonic ester. The addition amount of the acid generator is 0.1 to 10 wt % of the total weight of the inner coating.

The inner coating further comprises a polymer binder P1, the polymer binder P1 can be selected from one or more of phenolic resin, polystyrene derivative, polyurethane, and a polyacrylic acid (ester) which is different from the polymer binder P, and the addition amount of polymer binder P1 is 1 to 40 wt % of the total weight of the inner coating.

The outer coating comprises an infrared radiation absorbing compound having a wavelength absorption range of 700 to 1200 nm and a polymer binder Q which is different from the inner coating, and the addition amount of the infrared radiation absorbing compound is 0.5 to 10 wt % of the total weight of the outer coating; the addition amount of the polymer binder Q is 80 to 99.5 wt % of the total weight of the outer coating.

The infrared radiation absorbing compound can be selected from one or more of a cyanine dye, an anthraquinone dye, a phthalocyanine dye, a quinonimine dye or a methine cyanine dye, and the polymer binder Q can be derived from one or more of phenolic resin, polystyrene derivative, polyurethane and polyacrylic acid which is different from the inner coating polymer binder P.

Optionally, the outer coating further comprises a dissolution inhibitor, the dissolution inhibitor can be selected from one or more of a triarylmethane dye, an onium salt, a ketone or an ester compound, and the addition amount of the dissolution inhibitor is 0.1 to 20 wt % of the total weight of the outer coating.

Optionally, the outer coating further comprises an acid generator , and the acid generator can be selected from one or more of onium salt, triazine, acid anhydride, and sulfonate, and the addition amount of the acid generator is 0.2 to 10 wt % of the total weight of the outer coating.

The positive-working imageable element is a positive-working lithographic printing plate precursor with a hydrophilic substrate. The hydrophilic substrate is preferably an aluminum substrate subjected to electrolytic roughening and anodizing treatment.

The present invention further provides a method for forming an image, wherein the method comprising: A) performing imagewise exposure of the imageable element using the infrared radiation with a wavelength of 700 to 1200 nm, so as to form an imaged element comprising exposed and unexposed areas, B) contacting the imaged element with an alkaline developer having a pH value of less than 14 to remove only the exposed area to produce an imaged and developed element.

The present invention further provides a lithographic printing plate obtained according to the above-mentioned method of forming an image.

The terms “imageable element” and “lithographic printing plate precursor” as used herein have similar properties.

The multi-layer imageable element of the present invention can be used in a variety of ways, and the preferred use is as a lithographic printing plate precursor, but this is not meant to be the only use of the present invention. For example, the imageable element of the present invention can also be used to prepare photoresists, printed circuit boards, microelectronics and micro-optical devices, or have other non-imaging applications such as in paint or coating compositions.

(1) The Components of the Imageable Element

The imageable element of the present invention generally comprises a substrate, an inner coating (also called “bottom layer”), and an outer coating (also called “top layer”) covering the inner coating. Before thermal imaging, the outer coating cannot be removed by alkaline developer, but after thermal imaging, the imaging (exposure) area of the outer coating can be removed by alkaline developer, and meanwhile the inner coating can also be removed by alkaline developer. There is a radiation absorbing compound in the imageable element of the present invention, and the radiation absorbing compound is generally a near-infrared radiation absorbing compound having an absorption wavelength in the range of 700 to 1200 nm. Preferably, all the compounds are separately present in the outer coating, but it can also be selected to be separately present in the outer coating and the inner coating at the same time.

The substrate of the imageable element in the present invention generally uses a material with a flat surface, and is firm, stable and tough, and is unchangeable in size under the conditions of use. The substrate can be any self-supporting material, including polymer films (such as polyester, polyethylene, polycarbonate, cellulose ester polymers, and polystyrene films), glass, ceramic, metal plates or foils, or rigid paper (including resin-coated paper and metallized paper), or a laminate of any of these materials (such as a laminate of aluminum foil and polyester film). The metal carrier comprises plates or foils of aluminum, copper, zinc, titanium and alloys thereof.

Preferably, the substrate of the lithographic printing plate precursor is composed of an aluminum carrier, which can be processed by techniques well known in the art, including physical graining, electrochemical graining, chemical graining, and anodizing treatment.

The aluminum carrier for chemical grinding and anodizing treatment can be further treated with silicate, dextrin, hexafluorosilicic acid, alkali metal phosphate solution containing alkali metal halide (such as sodium fluoride), poly(vinyl phosphonic acid) (PVPA), vinyl phosphonic acid copolymer, poly(acrylic acid) or acrylic copolymer to form a hydrophilic layer. Preferably, the grained and anodized aluminum carrier of the present invention is treated with an alkali metal phosphate solution using a known procedure to improve the surface hydrophilicity.

The thickness of the substrate is variable, but it should be sufficient to withstand the abrasion from printing and thin enough to wrap around the printing plate. A preferred embodiment comprises aluminum foil with a thickness of 0.1 to 0.6 mm.

The substrate may also be a cylindrical surface on which various layer compositions are applied and thus constitute an integral part of the printer. The use of this type of imaging cylinder is described in, for example, U.S. Pat. No. 5,713,287.

The inner coating of the imageable element in the present invention comprises at least one polymer binder P, which is derived from a repeating unit of a maleimide monomer and a (meth)acrylamide monomer and is soluble in an alkaline developer solution. The polymer binder P comprised in the inner coating can be represented by the following structural formula (I):

—(A)x-(B)y-(C)— (I)

A represents a repeating unit derived from one or more maleimide monomers

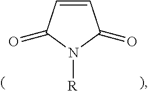

wherein R can be optionally substituted or unsubstituted alkyl, substituted or unsubstituted cycloalkyl, substituted or unsubstituted aryl, substituted or unsubstituted heteroaryl, hydroxyl, substituted or unsubstituted alkoxy, for example but not limited to: methyl, ethyl, propyl, isopropyl, tert-butyl, chloroethyl, 2-hydroxyethyl, 2-carboxyethyl, 6-aminohexyl, cyclopentyl, cyclohexyl, 4-methylcyclohexyl, phenyl, 3-methylphenyl, 4-hydroxyphenyl, 3-methyloxyphenyl, 4-carboxyphenyl, 2-nitrophenyl, 2,4,6-trichlorophenyl, 4-cyanophenyl, naphthyl, anthryl, pyrenyl, 2-furanyl, 3-pyrrolyl, pyridyl, indolyl, triazolyl, imidazolyl, hydroxyl, and preferably R is methyl, ethyl, cyclohexyl, phenyl, 4-hydroxyphenyl, 4-carboxyphenyl.

B represents a repeating unit derived from one or more (meth)acrylamide monomers

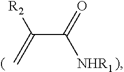

where R₁ can be optionally hydrogen, substituted or unsubstituted alkyl, substituted or unsubstituted cycloalkyl, substituted or unsubstituted aryl, substituted or unsubstituted heteroaryl, hydroxyl, substituted or unsubstituted alkoxy, for example but not limited to: hydrogen, methyl, ethyl, propyl, isopropyl, tert-butyl, hydroxymethyl, 2-hydroxyethyl, 3-aminopropyl, cyclopentyl, cyclohexyl, phenyl, benzyl, 3-methylphenyl, 4-hydroxyphenyl, 3-methoxyphenyl, 4-carboxyphenyl, 2-nitrophenyl, 2,4,6-trichlorophenyl, 4-cyanophenyl, naphthyl, anthryl, pyrenyl, pyridyl, indolyl, triazolyl, imidazolyl, hydroxymethyl, methoxy, butoxy, and preferably R₁ is hydrogen, methyl, ethyl, phenyl, benzyl, 2-hydroxyethyl, 4-hydroxyphenyl. R₂ can be optionally hydrogen or methyl.

C represents a repeating unit derived from one or more other ethylenically unsaturated polymerizable monomers different from A and B, preferably from but not limited to, for example: methyl (meth)acrylate, ethyl (meth)acrylate, butyl (meth)acrylate, benzyl (meth)acrylate, cetyl (meth)acrylate, hydroxyethyl (meth)acrylate, phenyl (meth)acrylate, N-(4-methylpyridyl) (meth)acrylate, (meth)acrylic acid, (meth)acrylonitrile, styrene, substituted styrene, 4-carboxy-styrene(ester), vinylpyridine, vinyl acetate, methyl vinyl ether, caprolactam, vinyl pyrrolidone, vinyl carbazole, maleic anhydride, maleic anhydride mono-ester, vinyl polyalkyl silane.

Meanwhile, based on the setting that the total weight of the polymer binder P having a structural formula (I) is x+y+z=100%, wherein any combination of x ranging from 1 to 85wt %, y rangin from 1 to 80wt % and z ranging form 1 to 80 wt % can be selected.

Generally, the polymer binder P present in the inner coating composition is 40 to 99.9 wt % of the total weight of the inner coating, preferably 70 to 99.9 wt %.

The polymer binder P can be prepared using known starting materials (monomers and polymerization initiators), solvents, and suitable reaction conditions. Representative synthesis methods are described in the embodiments below.

In order to color the coating of the present invention, a background contrast dye can be added to the inner coating. Dyes with high absorption in the visible light region are suitable to be used as background contrast dyes, preferably oil-soluble dyes and basic dyes. Specific examples of background contrast dyes can be selected from methyl violet, ethyl violet, crystal violet, malachite green, brilliant green, victoria pure blue, victoria blue R, victoria blue BO, rhodamine B, methylene blue, oil-soluble yellow 101, oil-soluble green BG, oil-soluble blue BOS, oil-soluble blue 603, oil-soluble black BY, oil-soluble black T-505, solvent black, and a mixture of one or more of the dyes described in Japanese Patent Publication No. 293247/1987. In addition, pigments such as phthalocyanine pigments, azo pigments, and titanium oxide can also be suitably used. Based on the total weight of the inner coating, the addition amount of the background contrast dye is 0.1 to 8 wt %, preferably 0.1 to 5 wt %.

The inner coating further comprises an infrared radiation absorbing compound, which may be selected from one or more of a cyanine dye, an anthraquinone dye, a phthalocyanine dye, a quinonimine dye or a methine cyanine dye. The representative infrared radiation absorbing compound will be described in detail when the outer coating is introduced below. The addition amount of the infrared radiation absorbing compound is 0.1 to 5 wt % of the total weight of the inner coating, preferably 0.1 to 3 wt %.

The inner coating further comprises an acid generator, which may be selected from one or more of onium salt, triazine, acid anhydride and sulfonate. The acid generator is a precursor that generates proton acid by thermally induced decomposition. According to the difference in electronegativity, acid generators can be divided into non-ionic acid generators and ionic acid generators, wherein the non-ionic acid generators comprise haloalkyl-substituted triazines, as described in U.S. Pat. No. 3,779,778, such as 2-phenyl-4,6-bis(trichloromethyl)s-triazine, 2,4,6-tris(trichloromethyl)s-triazine, 2-methyl-4,6-bis(trichloromethyl)s-triazine. The non-ionic acid generators also comprise anhydrides of organic acids, such as acetic anhydride, phthalic anhydride, tetrahydrophthalic anhydride, hexahydrophthalic anhydride, maleic anhydride, pyromellitic dianhydride. The non-ionic acid generators also comprise sulfonic esters, such as aryl p-toluenesulfonate, N-hydroxyphthalimide p-toluenesulfonate, oxime sulfonate, naphthoquinone diazide sulfonate. Ionic acid generators comprise onium salts, wherein the onium cation is iodonium, sulfonium, phosphonium, oxysulphoxonium, oxysulphonium, quaternary ammonium salt, diazonium, or arsonium. Commonly used onium salts comprise diphenyl iodonium salt, triphenyl sulfonium salt, phenyl diazonium salt, tetraalkyl quaternary ammonium salt, tetraaryl quaternary ammonium salt, amino acid inner salt and the acid generator described in U.S. Pat. Nos. 6,787,281, 5,491,046, 7,217,499 and 7,033,722. The preferred acid generators of the present invention comprise Irgacure 250 (produced by Ciba), BC (produced by Sanbo Chemical), WPI-169, WPI-170 (produced by Wako), triazine D and triazine B. The addition amount of the acid generator is 0.1 to 10 wt % of the total weight of the composition, preferably 1 to 5 wt %.

The inner coating further comprises another polymer binder Pi, the binder Pi can be selected from one or more of modified phenolic resins, polystyrene derivatives, polyurethanes, and a polyacrylic acids (esters). Generally speaking, from the viewpoint of not impairing the sensitivity of the imageable element, the polymer binder is usually an alkali-soluble polymer. The preferred polymer binder Pi of the present invention is phenolic resin and polyacrylic acid (ester), comprising condensation polymers of phenol and formaldehyde, condensation polymers of m-cresol and formaldehyde, condensation polymers of p-cresol and formaldehyde, condensation polymers of a mixture of m/p-cresol and formaldehyde, condensation polymers of phenol and cresol (m, p or a mixture of m/p) and formaldehyde, and condensation copolymers of palmitoyl phenol and acetone. The addition amount of the binder is 1 to 40 wt % of the total weight of the composition, preferably 1 to 20 wt %.

In addition, the inner coating composition of the present invention can further comprise various additives in conventional amounts, such as dispersants, moisturizers, biocides, plasticizers, surfactants for coatability or other properties, tackifiers, fillers and extenders, pH regulators, desiccants, defoamers, preservatives, antioxidants, development aids, rheology modifiers or any combination thereof, or other additions commonly used in lithographic printing technology.

The outer coating composition in the present invention comprises at least an infrared radiation absorbing compound having a wavelength absorption ranging from 700 to 1200 nm, preferably 700 to 1200 nm. This compound (sometimes called a “photothermal conversion material” or “thermal conversion agent”) absorbs radiation and converts it into heat. This compound may be a dye, carbon black or a pigment, preferably a dye, and more preferably a near-infrared absorbing cyanine dye. Examples of usable pigments are ProJet 900, ProJet 860 and ProJet 830 (all available from Zeneca Corporation). Available carbon black compounds such as FX-GE-003 (manufactured by Nippon Shokubai) or carbon black surface-functionalized with anionic groups such as CAB-O-JET® 200 or CAB-O-JET 300® (manufactured by Cabot Corporation). Examples of suitable dyes comprise but are not limited to one or more of cyanine dyes, anthraquinone dyes, phthalocyanine dyes, quinonimine dyes, azo dyes, squaraine dyes, croconate dyes, triarylamine dyes, thiazolium dyes, indolium dyes, oxacyanine dyes, thmzolmm dyes, indocyanine dyes, indoaniline dyes, indole tricarbocyanine dyes, oxatricarbocyanine dyes, thiocyanine dyes, thiatricarbocyanine dyes, merocyanine dyes, cryptocyanine dyes, naphthocyanine dyes, polyaniline dyes, polypyrrole dyes, polythiophene dyes, oxazine dyes, naphthoquinone dyes, methine dyes and porphyrin dyes. Other suitable dyes can be found in numerous publications including U.S. Pat. Nos. 6,294,311 and 5,208,135 and references cited therein.

Commonly used near-infrared absorbing cyanine dyes can be found in, for example, U.S. Pat. Nos. 6,309,792, 6,264,920 and U.S. Pat. No. 6,787,281. Suitable dyes can be formed by conventional methods and starting materials or can be obtained from various commercial sources, such as IRD-85 and IRD-67 from DKSH.

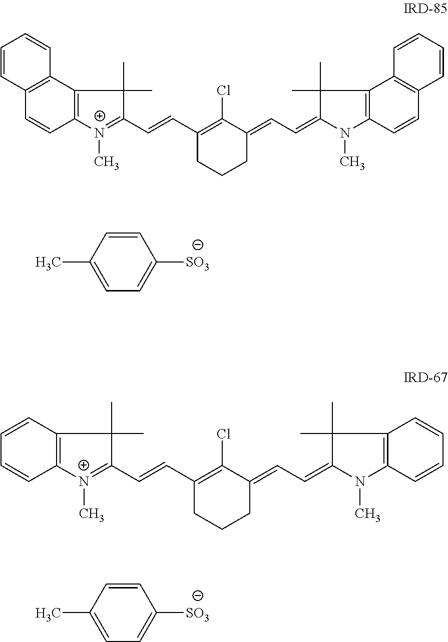

In addition to low molecular weight IR-absorbing dyes, IR dye moieties combined with polymers can also be used, that is, IR dye salt absorbing substance, in which cations of IR dye moiety are used to ionically interact with polymer side chains containing functional groups such as carboxyl, sulfo, phosphor or phosphono.

The infrared radiation absorbing compound may generally be present in an amount of 0.1% to 20 wt %, preferably 1 to 6 wt % of the total weight of the outer coating. It is easy for those skilled in the art to determine the specific amount of the infrared radiation absorbing compound.

The outer coating composition of the present invention further comprises at least one polymer binder Q. Any polymer binder that has been used in the outer coating of the multilayer thermal imageable element in the previous literature can be used as an outer coating composition of the imageable element in the present invention. The polymer binder Q can be derived from one or more of phenolic resin, poly(hydroxystyrene), polyurethane and polyacrylic acid(ester).

Preferably, the polymer binder Q in the outer coating is a phenolic resin comprising multiple phenolic hydroxyl groups that is insoluble in water and soluble in alkaline developers, or other polymers containing one or more phenolic hydroxyl groups on the main chain or on the side groups, for example, novolac resins, resole phenol resins, acrylic resins containing phenolic side groups, and polyvinyl phenol resins, phenol resins are preferred. More preferred is novolac resin.

Novolac resins are commercially available and well known in the art. Novolac resins are usually prepared by the condensation reaction of phenols such as phenol, m-cresol, o-cresol, p-cresol, etc. with aldehydes such as formaldehyde, polyformaldehyde, acetaldehyde, etc. or ketones such as acetone in the presence of an acid catalyst. The weight average molecular weight is usually 1,000 to 30,000. Typical novolac resins comprise, for example, phenol-formaldehyde resin, cresol-formaldehyde resin, phenol- cresol-formaldehyde resin, p-tert-butyl phenol-formaldehyde resin, and pyrogallol-acetone resin. Particularly useful novolac resins are prepared by reacting m-cresol, a mixture of m-cresol and p-cresol, or phenol with formaldehyde under conditions well known to those skilled in the art.

Examples of commonly used hydroxyl-containing polymers comprise EP0090, NTR6050 (Asahi); ALNOVOL SPN452, SPN465, SPN400, (Clariant GmbH); DURITE PD443, PD423A, PD140A (Borden Chemical, Inc.); BAKELITE 9900, 6564LB, 6866LB03 (Bakelite AG). Particularly useful polymers are PD140A and EP0090 described in the embodiments below.

In addition to or instead of the above phenolic resins, the outer coating may also comprise non-phenolic polymer materials as the film-forming base material. Such non-phenolic polymer materials comprise polymers formed from maleic acid and one or more styrene monomers (i.e. styrene and styrene derivatives with various substituents on the benzene ring), polymers formed from methacrylate and one or more carboxyl-containing monomers, and a mixture thereof. The maleic anhydride-derived polymer usually comprises 1 to 50% moles of maleic anhydride-derived repeating units, and the remaining repeating units are derived from styrene monomers and optionally other polymerizable monomers. Polymers derived from (meth)acrylates and formed from carboxyl-containing monomers generally comprise 80 to 98% moles of (meth)acrylate repeating units. The carboxyl-containing repeating unit can be derived from, for example, acrylic acid, methacrylic acid, itaconic acid, maleic acid, and similar monomers well known in the art.

The polymer binder in the outer coating may also use a hydroxystyrene polymer, for example, containing a repeating unit derived from 4-hydroxystyrene.

The addition amount of the polymer binder Q is 80 to 99.5 wt % of the total weight of the outer coating, preferably 80 to 95 wt %.

The outer coating composition of the present invention may also optionally further comprises a dissolution inhibitor, which usually has a polar functional group, which is considered to be used as a receiving site for hydrogen bonding with, for example, the hydroxyl group of the polymer binder Q. The most common dissolution inhibitor is a mixture of one or more of triarylmethane dyes such as methyl violet, ethyl violet, crystal violet, malachite green, brilliant green, victoria blue B, victoria blue R, victoria blue BO, BASONYL violet 610. These compounds can also be used as background dyes for color development of the outer coating.

Compounds containing positively charged (i.e. quaternized) nitrogen atoms can also be used as dissolution inhibitors, such as tetra-alkylammonium compounds, quinolinium compounds, benzothiazolium compounds, and pyridinium compounds and imidazolium compounds. Representative tetra-alkylammonium dissolution inhibitor compounds comprise tetrapropylammonium bromide, tetraethylammonium bromide, tetrapropylammonium chloride, tetramethylalkylammonium chloride, and trimethylalkylammonium bromide such as trimethyl octyl ammonium bromide and trimethyl decyl ammonium chloride. Representative quinolinium dissolution inhibitor compounds comprise 1-ethyl-2-methylquinoline iodide. Representative benzothiazolium compounds comprise 3-ethyl-2-methyl benzothiazole iodide.

Diazonium salts can also be used as dissolution inhibitor compounds, which comprise, for example, substituted and unsubstituted diphenylamine diazonium salts such as methoxy-substituted diphenylamine diazonium hexafluorophosphate. Ester compounds can also be used as dissolution inhibitor compounds. Representative sulfonates comprise ethyl benzenesulfonate, n-hexyl benzenesulfonate, ethyl p-toluenesulfonate, tert-butyl p-toluenesulfonate and phenyl ester p-toluenesulfonate. Representative phosphate esters comprise trimethyl phosphate, triethyl phosphate, and tricresyl phosphate. Usable sulfones comprise those containing aromatic groups such as diphenyl sulfone.

Another polymer material that contains polar groups and functions as a dissolution inhibitor is one in which part of the phenolic hydroxyl groups have been converted into sulfonate (preferably benzenesulfonate or p-toluenesulfonate). There are also derivatized phenolic resins containing diazonaphthoquinone functional groups. The polymerized diazonaphthoquinone compound comprises a derivatized resin formed by the reaction of a reactive derivative containing a diazonaphthoquinone moiety with a polymer material containing a suitable reactive group such as a hydroxyl group or an amino group. The derivatization of phenolic resins with compounds containing diazonaphthoquinone groups is well known in the art and is described in, for example, U.S. Pat. Nos. 5,705,308 and 5,705,332. Other useful solvent inhibitor compounds are described in, for example, U.S. Pat. Nos. 5,705,308, 6,060,222, and 6,130,026. When the dissolution inhibitor compound is present in the outer coating, it usually amounts for 0.1 to 20 wt % of the total weight of the outer coating, preferably 1 to 15 wt %.

The outer coating of the present invention may also contain an acid generator, which may be a mixture of one or more of the acid generators described in the inner coating, and the addition amount of the acid generator is 0.1 to 10 wt % of the total weight of the outer coating, preferably 1 to 5 wt %.

In addition, the outer coating in the present invention can further comprise various additives in conventional amounts, such as surfactants, leveling agents, dispersing aids, wetting agents, biocides, tackifiers, and desiccants, defoamers, preservatives, antioxidant. Coating surfactants and leveling agents are particularly useful.

(2) Preparation Method of an Imageable Element

The imageable element, i.e., the lithographic printing plate precursor of the present invention, is prepared by coating the above-mentioned inner coating on the substrate carrier, and then coating the above-mentioned outer coating on the inner coating. Specifically, the inner coating and outer coating are separately dispersed or dissolved in a suitable coating solvent, and suitable equipment and procedures such as spin coating, knife coating, gravure coating, and die coating, slit coating, bar coating, wire wound coating, roller coating or extrusion hopper coating are used to apply the inner coating solution to the surface of the substrate carrier. The solvent of the inner coating is removed by drying in an oven at 70 to 160° C., and then the outer coating solution is applied to the surface of the inner coating, and the solvent of the outer coating is also removed by drying in an oven at 70 to 160° C., thus obtaining the lithographic printing plate precursor. The coverage rate of the inner coating is usually 0.3 to 3.5 g/m², and preferably 0.5 to 2.5 g/m²; the coverage rate of the outer coating is usually 0.1 to 3.5 g/m², and preferably 0.3 to 1.8 g/m².

The selection of the coating solvent herein depends on the properties of the polymer binders and other components in the infrared radiation-sensitive composition, typically the coating solvents used under the conditions and techniques well known in the art include, for example, one or more of acetone, methyl ethyl ketone, diethyl ketone, methyl isobutyl ketone, ethylene glycol, 1-methoxy-2-propanol, 2-ethoxy-ethanol, methyl lactate, γ-butyrolactone, 1,3-dioxolane, tetrahydrofuran and water.

In fact, the imageable element of the present invention can be in any form, including but not limited to printing plate precursors, printing cylinders, printing sleeves, and printing belts (including flexible printing webs). Preferably, the imageable element of the present invention is a lithographic printing plate precursor used to form a lithographic printing plate.

(3) Imaging and Development of Imageable Elements

For the embodiment of the present invention, the laser used to expose the lithographic printing plate precursor of the present invention may be a diode laser due to reliability and low maintenance of diode laser systems, however, other lasers such as gas or solid lasers can also be used. The combination of power, intensity and exposure time of laser imaging will be obvious to those skilled in the art. Currently, high-performance lasers or laser diodes used in commercially available image digital plate making machine has an emission wavelength of 800 to 850 nm. The imaging device can be configured as a flat-bed recorder or a drum recorder in which an imageable member is mounted to the inner or outer cylindrical surface of the drum. The preferred imaging device is available from an image platemaking machine modeled as Kodak Trendsetter® Q800 of the Eastman Kodak Company (Rochester, N. Y., USA), which comprises a laser diode emitting near-infrared radiation with a wavelength of 830 nm. Other optional imaging sources include image plate-making machines of PlateRite 4300 series or 8600 series of Screen Holdings Co., Ltd. (Kamigyo-ku, Kyoto, Japan). The imaging energy can generally be in the range of 50 to 500 mJ/cm², preferably less than 250 mJ/cm², and most preferably less than 150 mJ/cm².

Although laser imaging is preferred in the practice of the present invention, the imaging can be provided by any other means of providing thermal energy in an image manner. For example, the imaging can be performed with a thermal resistance head in the so-called “thermal printing” and the means as used in thermal facsimile machines and sublimation printers, as described in, for example, U.S. Pat. No. 5,488,025.

The imaging process of the imageable element produces a quasi-imaging element of the latent image comprising an imaged (exposed) area and an unimaged (unexposed) area, and then the quasi-imaging element is washed with a suitable alkaline developer aqueous solution to remove the outer coating of the exposed area and the inner coating underneath, thus exposing the hydrophilic surface of the substrate. More specifically, the development time should be sufficient to remove the outer coating and the inner coating of the exposed area but not long enough to remove the coating of the unexposed area. Therefore, the imageable element is “positive”.

In the embodiment of the present invention, the pH value of such an aqueous alkaline developer aqueous solution is usually at least 9, and preferably at least 11. Optional aqueous alkaline developer solution of the present invention comprises DV-T, DV-T1, DV-PT (available from Zhejiang Konita New Materials Co., Ltd.), GOLDSTAR Developer, GOLDSTAR Plus Developer, GOLDSTAR Premium Developer, K300, K400 (Both available from Eastman Kodak Company) and THD-200 (available from Agfa). These alkaline developer aqueous solutions usually further comprise surfactants, chelating agents and various alkaline agents such as inorganic metasilicates, organic metasilicates, hydroxides and carbonates.

The aqueous alkaline developer solution usually further comprises one or more water-miscible organic solvents. Usable organic solvents comprise reaction products of phenol with ethylene oxide and propylene oxide, such as ethylene glycol ethyl ether, ethylene glycol butyl ether, propylene glycol monomethyl ether, glycerol (ether), etc. The organic solvent is usually present in an amount of 0.5 to 15 wt % of the total mass of the developer. Representative solvent-based alkaline developers comprise ND-1 developer, 955 developer, and 956 developer (commercially available from Eastman Kodak Company).

After the imageable element is developed, the imageable element can be washed with water and dried in a suitable manner. It can also be treated with a conventional gum solution, preferably gum arabic, or the imaged element can be placed in an oven for the baking treatment, such as baking at 220 to 240° C. for 7 to 10 min, or at 120° C. for 30 min, which can further increase the operating life of the resulting imaging element.

Finally, the ink and fountain solution are coated to the printing surface of the imageable element on a lithography offset press for printing. The ink is absorbed by unexposed or unremoved areas of the imaging element, while the dampening solution is absorbed by exposed areas and the hydrophilic surface of the substrate carrier exposed by the development process. The ink is then transferred to a suitable receiving material such as cloth, paper, metal, glass or plastic. Also, “transfer roller” can be used to transfer ink from the imageable element to the receiving material.

Compared with the prior art, the technical solution of the present invention has the following advantages:

1. The imageable element of the present invention can be radiation-sensitive in a wavelength range of 700 to 1200 nm by designing the polymer binder P, and is an excellent radiation-sensitive positive-working lithographic printing plate precursor. The lithographic printing plate prepared by the precursor has excellent resistance to the erosion of isopropanol. Therefore, the imageable element prepared by the infrared sensitive composition of the present invention is not easy to be corroded and dissolved by printing chemicals during the printing process, which is beneficial to prolong the service life of the lithographic printing plate precursor.

2. The imageable element of the present invention adopts double-layer coating technology. Compared with single-layer coating products, it has an advantage of separating the functions of the resin into their respective coatings, maximizing the anti-solvent performance and photosensitive speed of the imageable layer.

### DETAILED DESCRIPTION OF EMBODIMENTS

The technical solutions of the present invention will be described in detail below with reference to specific examples. Obviously, the described examples are part of the embodiments of the present invention, rather than all of the embodiments. Based on the examples of the present invention, all other embodiments obtained by those skilled in the art without creative work shall fall within the protection scope of the present invention. In addition, the technical features involved in different examples of the present invention described below can be combined with each other as long as they do not conflict with each other. The following examples are provided to illustrate the implementation of the present invention and are not intended to limit the present invention in any way.

The following is a synthesis example of the polymer binder P, which are expressed as polymer binder PB-a, polymer binder PB-b etc. according to the order of the synthesis examples for convenience of distinction.

### Synthesis Example A: Synthesis of Polymer Binder PB-a

4.0 g of p-hydroxyphenyl acrylamide, 15.5 g of N-p-methylphenyl maleimide, 0.5 g of methacrylic acid, 0.2 g of free radical initiator AIBN and 60 g of ethylene glycol monomethyl ether were added into a 250 ml four-neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.1 g of AIBN was added therein, the reaction was stirred at 65 to 75° C. under the protection of nitrogen for 15 h. After cooling, the reaction mixture was added dropwise to 400 g of stirring methanol (in which 2 drops of concentrated hydrochloric acid was added). The precipitated solid was collected by suction filtration, and then added into 250 g of cold water and stirred for 15 min. A rude product was collected by suction filtration, dried by spreading out on filter paper overnight, and finally dried in an oven at 45° C. Yield: 13.5 g of yellowish solid was obtained.

### Synthesis Example B: Synthesis of Polymer Binder PB-b

6.0 g of p-sulfonamidophenyl acrylamide, 13.5 g of N-p-methylphenyl maleimide, 0.5 g of methacrylic acid, 0.2 g of AIBN and 60 g of N,N-dimethylacetamide were added into a 250 ml four-neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.1 g of AIBN was added therein, the reaction was stirred at 65 to 75° C. under the protection of nitrogen for 15 h. After cooling, the reaction mixture was added dropwise to 400 g of stirring methanol (in which 2 drops of concentrated hydrochloric acid was added). The precipitated solid was collected by suction filtration, and then added into 250 g of cold water and stirred for 15 min. A rude product was collected by suction filtration, dried by spreading out on filter paper overnight, and finally dried in an oven at 45° C. Yield: 16.0 g yellowish solid was obtained.

### Synthesis Example C: Synthesis of Polymer Binder PB-c

7.5 g of p-sulfonamidophenyl acrylamide, 10.5 g of N-phenylmaleimide, 2 g of methyl methacrylate, 0.2 g of AIBN and 60 g of ethylene glycol monomethyl ether were added to a 250 ml four-neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.1 g of AIBN was added therein, the reaction was stirred at 65 to 75° C. under the protection of nitrogen for 15 h. After cooling, the reaction mixture was added dropwise to 400 g of stirring methanol (in which 2 drops of concentrated hydrochloric acid was added). The precipitated solid was collected by suction filtration, and then added into 250 g of cold water and stirred for 15 min. A rude product was collected by suction filtration, dried by spreading out on filter paper overnight, and finally dried in an oven at 45° C. Yield: 17.2 g yellowish solid was obtained.

### Synthesis Example D: Synthesis of Polymer Binder PB-d

4.5 g of p-hydroxyphenylacrylamide, 9 g of N-phenylmaleimide, 11 g of acrylonitrile, 12 g of methyl methacrylate, 3.5 g of methacrylic acid, 0.4 g of AIBN and 120 g of ethylene alcohol monomethyl ether was added to a 250 ml four to neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.2 g of AIBN was added therein, the reaction was stirred at 65 to 75° C. under the protection of nitrogen for 15 h. After cooling, the reaction mixture was added dropwise to 800 g of stirring water (in which 4 drops of concentrated hydrochloric acid was added). The precipitated solid was collected by suction filtration, and then added into 500 g of cold water and stirred for 15 min. A rude product was collected by suction filtration, dried by spreading out on filter paper overnight, and finally dried in an oven at 45° C. Yield: 37.9 g yellowish solid was obtained.

### Synthesis Example E: Synthesis of Polymer Binder PB-e

10.0 g of N-p-ethylphenylmaleimide, 4.0 g of p-hydroxyphenyl acrylamide and 110 g of N,N-dimethylacetamide were added to a 250 ml four-neck round bottom flask equipped with a heating jacket, a temperature controller, a mechanical stirrer, a condenser, a constant pressure dropping funnel, and a nitrogen inlet and outlet. The constant pressure dropping funnel is filled with a mixture in which 0.4 g AIBN was dissolved in 10 g N,N-dimethylacetamide, 4.0 g methyl methacrylate, 4.0 g styrene, 4.0 g methacrylic acid, and 14 g acrylonitrile. The mixture in the flask was heated to 70° C. under the protection of nitrogen, and the monomer mixture in the constant pressure funnel was added dropwise to the flask within about 30 min, and the reaction was stirred at this temperature for 5 h. Further, 0.2 g of AIBN was added therein, the reaction was stirred at 65 to 75° C. under the protection of nitrogen for 15 h. After cooling, the reaction mixture was added dropwise to 800 g of stirring water (in which 4 drops of concentrated hydrochloric acid was added). The precipitated solid was collected by suction filtration, and then added into 500 g of cold water and stirred for 15 min. A rude product was collected by suction filtration, dried by spreading out on filter paper overnight, and finally dried in an oven at 45° C. Yield: 40.2 g yellowish solid was obtained.

### Synthesis Example F: Synthesis of Polymer Binder PB-f

6.2 g of methacrylamide, 11.6 g of N-phenylmaleimide, 2.2 g of methacrylic acid, 0.2 g of AIBN and 60 g of ethylene glycol monomethyl ether were added to a 200 ml four-neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.1 g of AIBN was added therein, the reaction was stirred at 65 to 75° C. under the protection of nitrogen for 15 h. After cooling, the reaction mixture was added dropwise to 400 g of stirring methanol (in which 2 drops of concentrated hydrochloric acid was added). The precipitated solid was collected by suction filtration, and then added into 250 g of cold water and stirred for 15 min. A rude product was collected by suction filtration, dried by spreading out on filter paper overnight, and finally dried in an oven at 45° C. Yield: 18.7 g yellowish solid was obtained.

### Synthesis Example G: Synthesis of Polymer Binder PB-g

Add 6.0 g of N,N-dimethylacrylamide, 12.8 g of N-p-hydroxyphenyl maleimide, 1.2 g of methacrylic acid, 0.2 g of AIBN and 60 g of ethylene glycol monomethyl ether were added into a 200 ml four-neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.1 g of AIBN was added therein, the reaction was stirred at 65 to 75° C. under the protection of nitrogen for 15 h. After cooling, the reaction mixture was added dropwise to 400 g of stirring methanol (in which 2 drops of concentrated hydrochloric acid was added). The precipitated solid was collected by suction filtration, and then added into 250 g of cold water and stirred for 15 min. A rude product was collected by suction filtration, dried by spreading out on filter paper overnight, and finally dried in an oven at 45° C. Yield: 17.9 g yellowish solid was obtained.

### Synthesis Example H: Synthesis of Polymer Binder PB-h

2.2 g of acrylamide, 5.4 g of N-phenylmaleimide, 4.0 g of ethyl methacrylate, 6.2 g of acrylonitrile, 2.2 g of methacrylic acid, 0.2 g of AIBN and 60 g of ethylene glycol monomethyl ether were added into a 200 ml four-neck round bottom flask equipped with a heating jacket, a temperature controller, a mechanical stirrer, a condenser and a nitrogen inlet and outlet. The reaction mixture was heated to 70° C. under the protection of nitrogen, and then the reaction was stirred at this temperature for 5 h. Further, 0.1 g of AIBN was added therein, the reaction was stirred at 65 to 75° C. under the protection of nitrogen for 15 h. After cooling, the reaction mixture was added dropwise to 400 g of stirring methanol (in which 2 drops of concentrated hydrochloric acid was added). The precipitated solid was collected by suction filtration, and then added into 250 g of cold water and stirred for 15 min. A rude product was collected by suction filtration, dried by spreading out on filter paper overnight, and finally dried in an oven at 45° C. Yield: 18.9 g yellowish solid was obtained.

The following are examples for preparing lithographic printing plate precursors, which are expressed as polymer binder PP-a, polymer binder PP-b . . . etc. in the order of synthesis examples for convenience of distinction.

### Imageable Element Example 1: Preparation of the Lithographic Printing Plate Precursor (PP-a)

(1) Inner coating: 0.50 g of polymer binder PB-a and 0.01 g of background dye victoria blue BO were dissolved in a mixed solvent of 6.5 g of ethylene glycol monoethyl ether, 2.0 g of butanone-2, 0.5 g of butyrolactone and 0.5 g of water. The above-mentioned composition solution was coated on the aluminum plate substrate which has been treated by electrochemical roughening and anodizing using a spin coating method, and then dried in an oven at 145 ° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.30 g of phenolic resin PD140A, 0.16 g of phenolic resin LB6564, 0.02 g of infrared absorber IRD-85 and 0.02 g of methyl violet were dissolved in a mixed solvent of 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-a) having a total weight of the inner coating and outer coating of approximately 2.1 g/m².

The resulting planography printing plate precursor (PP-a) prepared in this example was subjected to scanning exposure by using 830 nm laser with a drum rotation speed of 220 rpm and a laser power of 12 W on a Kodak 800 Quantum-II type CTP platesetter. The exposed original plate was developed with Konita DV-T developer solution at 25° C. for 30 s. After which, the coating on the exposed area of the resulting lithographic printing plate precursor was completely dissolved, while the coating on the unexposed area remained. The image was clear and the edges were sharp and neat.

### Imageable Element Example 2: Preparation of the Lithographic Printing Plate Precursor (PP-b)

(1) Inner coating: 0.50 g of polymer binder PB-b, 0.005 g of infrared absorber IRD-85, 0.01 g of acid generator WPI-169 and 0.01 g of victoria blue BO were dissolved in a mixed solvent of 6.5 g ethylene glycol monoethyl ether, 2.0 g of butanone-2, 0.5 g of butyrolactone and 0.5 g of water. The above-mentioned composition solution was coated on the aluminum plate substrate which has been treated by electrochemical roughening and anodizing using a spin coating method, and then dried in an oven at 145° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.45 g of phenolic resin PD-140A, 0.02 g of infrared absorber IRD-85, 0.01 g of acid generator triazine B and 0.02 g of methyl violet were dissolved in a mixed solvent of 5.8 g propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-b) with a total weight of the inner coating and outer coating of approximately 2.1 g/m².

The resulting planography printing plate precursor (PP-b) prepared in this example was subjected to scanning exposure by using 830 nm laser with a drum rotation speed of 220 rpm and a laser power of 12 W on a Kodak 800 Quantum-II type CTP platesetter. The exposed original plate was developed with Konita DV-T developer solution diluted with water at 25° C. for 35 s. After which, the coating on the exposed area of the resulting lithographic printing plate precursor was completely dissolved, while the coating on the unexposed area remained. The image was clear and the edges were sharp and neat.

### Imageable Element Example 3: Preparation of the Lithographic Printing Plate Precursor (PP-c)

(1) Inner coating: 0.45 g of polymer binder PB-c, 0.05 g of phenolic resin PD494A and 0.01 g of victoria blue BO were dissolved in a mixed solvent of 4.5 g of ethylene glycol monomethyl ether, 3.5 g of butanone-2, and 1.0 g of butyrolactone and 1.0 g of water. The above-mentioned composition solution was coated on the aluminum plate substrate which has been treated by electrochemical roughening and anodizing using a spin coating method, and then dried in an oven at 145 ° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.46 g phenolic resin BTB-225, 0.02 g infrared absorber IRD-67, 0.01 g of acid generator Irgacure 250 and 0.02 g of methyl violet were dissolved in a mixed solvent of 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP to c) having a total weight of the inner coating and outer coating of approximately 2.1 g/m².

The resulting lithographic printing plate precursor (PP-c) prepared in this example was subjected to scanning exposure by using 830 nm laser with a drum rotation speed of 220 rpm and a laser power of 12 W on a Kodak 800 Quantum-II type CTP platesetter. The exposed original plate was developed with Konita DV-T developer solution at 25° C. for 35 s. After which, the coating on the exposed area of the resulting lithographic printing plate precursor was completely dissolved, while the coating on the unexposed area remained. The image was clear and the edges were sharp and neat.

### Imageable Element Example 4: Preparation of the Kithographic Printing Plate Precursor (PP-d)

(1) Inner coating: 0.50 g of polymer binder PB-d and 0.01 g of victoria blue BO were dissolved in a mixed solvent of 4.5 g of ethylene glycol monomethyl ether, 3.5 g of butanone-2, 1.0 g of butyrolactone and 1.0 g of water. The above-mentioned composition solution was coated on the aluminum plate substrate which has been treated by electrochemical roughening and anodizing using a spin coating method, and then dried in an oven at 145° C. for 3 min to obtain the inner coating having a weight of 1.2 g/m². The inner coating did not dissolve or fall off significantly after soaking in isopropanol for 1 min, showing its excellent alcohol resistance.

(1) Outer coating: 0.46 g of phenolic resin PD-140A, 0.02 g of infrared absorber IRD-85 and 0.02 g of methyl violet were dissolved in a mixed solvent of 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-d) having a total weight of the inner coating and outer coating of approximately 2.1 g/m².

The resulting planographic printing plate precursor (PP-d) prepared in this example was subjected to scanning exposure by using 830 nm laser with a drum rotation speed of 220 rpm and a laser power of 12 W on a Kodak 800 Quantum-II type CTP platesetter. The exposed original plate was developed with Konita DV-T developer solution diluted with water at 25° C. for 15 s. After which, the coating on the exposed area of the resulting lithographic printing plate precursor was completely dissolved, while the coating on the unexposed area remained. The image was clear and the edges were sharp and neat.

### Imageable Element Example 5: Preparation of a Lithographic Printing Plate Precursor (PP-e)

(1) Inner coating: 0.50 g of polymer binder PB-e, 0.005 g of infrared absorber IRD67 and 0.01 g of victoria blue BO were dissolved in a mixed solvent of 4.5 g of ethylene glycol monomethyl ether, 3.5 g of butanone-2, 1.0 g of butyrolactone and 1.0 g of water. The above-mentioned composition solution was coated on the aluminum plate substrate which has been treated by electrochemical roughening and anodizing using a spin coating method, and then dried in an oven at 145 ° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.23 g of phenolic resin PD-140A, 0.23 g of phenolic resin LB6564, 0.02 g of infrared absorber IRD-85 and 0.02 g of methyl violet were dissolved in a mixed solvent of 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-e) having a total weight of the inner coating and outer coating of approximately 2.1 g/m².

The resulting planographic printing plate precursor (PP-e) prepared in this example was subjected to scanning exposure by using 830 nm laser with a drum rotation speed of 220 rpm and a laser power of 12 W on a Kodak 800 Quantum-II type CTP platesetter. The exposed original plate was developed with a mixture of Konita DV-T developer and ethylene glycol at 25° C. for 35 s. After which, the coating on the exposed area of the resulting lithographic printing plate precursor was completely dissolved, while the coating on the unexposed area remained. The image was clear and the edges were sharp and neat.

### Imageable Element Example 6: Preparation of a Lithographic Printing Plate Precursor (PP-f)

(1) Inner coating: 0.50 g of polymer binder PB-f and 0.01 g of victoria blue BO were dissolved in a mixed solvent of 6.5 g of ethylene glycol monoethyl ether, 2.0 g of butanone-2, 0.5 g of butyrolactone and 0.5 g of water. The above-mentioned composition solution was coated on the aluminum plate substrate which has been treated by electrochemical roughening and anodizing using a spin coating method, and then dried in an oven at 145° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.46 g of phenolic resin PD-140A, 0.02 g of infrared absorber IRD-85 and 0.02 g of methyl violet were dissolved in a mixed solvent of 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-f) with a total weight of the inner coating and outer coating of approximately 2.1 g/m².

The resulting lithographic printing plate precursor (PP-f) prepared in this example was subjected to scanning exposure by using 830 nm laser with a drum rotation speed of 220 rpm and a laser power of 12 W on a Kodak 800 Quantum-II type CTP platesetter. The exposed original plate was developed with a mixture of Konita DV-T developer and ethylene glycol methyl ether at 25° C. for 35 s. After which, the coating on the exposed area of the resulting lithographic printing plate precursor was completely dissolved, while the coating on the unexposed area remained. The image was clear and the edges were sharp and neat.

### Imageable Element Example 7: Preparation of the Lithographic Printing Plate Precursor (PP-g)

(1) Inner coating: 0.45 g of polymer binder PB-g, 0.05 g of a copolymer of methyl methacrylate and methacrylic acid and 0.01 g of victoria blue BO were dissolved in a mixed solvent of 6.5 g of ethylene glycol monoethyl ether and 2.0 g of butanone-2, 0.5 g of butyrolactone and 0.5 g of water. The above-mentioned composition solution was coated on the aluminum plate substrate which has been treated by electrochemical roughening and anodizing using a spin coating method, and then dried in an oven at 145 ° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.46 g of phenolic resin EP0090G, 0.02 g of infrared absorber IRD-85, 0.01 g of acid generator WPI-170 and 0.02 g of methyl violet were dissolved in a mixed solvent 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-g) having a total weight of the inner coating and outer coating of approximately 2.1 g/m².

The resulting planography printing plate precursor (PP-g) prepared in this example was subjected to scanning exposure by using 830 nm laser with a drum rotation speed of 220 rpm and a laser power of 12 W on a Kodak 800 Quantum-II type CTP platesetter. The exposed original plate was developed with Konita DV-T developer solution diluted with water at 25° C. for 35 s. After which, the coating on the exposed area of the resulting lithographic printing plate precursor was completely dissolved, while the coating on the unexposed area remained. The image was clear and the edges were sharp and neat.

### Imageable Element Example 8: Preparation of a Lithographic Printing Plate Precursor (PP-h)

(1) Inner coating: 0.23 g of polymer binder PB-h, 0.23 g of polymer binder PB-f and 0.01 g of victoria blue BO were dissolved in a mixed solvent of 6.5 g of ethylene glycol monoethyl ether, 2.0 g of butanone-2, 0.5 g of butyrolactone and 0.5 g of water. The above-mentioned composition solution was coated on the aluminum plate substrate which has been treated by electrochemical roughening and anodizing using a spin coating method, and then dried in an oven at 145° C. for 3 min to obtain the inner coating having a weight of 1.2 g/m². The inner coating did not dissolve or fall off significantly after soaking in isopropanol for 1 min, showing its excellent alcohol resistance.

(2) Outer coating: 0.46 g of phenolic resin PD-140A, 0.02 g of infrared absorber IRD-85, 0.01 g of acid generator triazine D and 0.02 g of methyl violet were dissolved in a mixed solvent of 5.8 g of propylene glycol monomethyl ether and 3.8 g of butanone-2. The composition solution was coated on the above-mentioned inner coating using a spin coating method, and then dried in an oven at 145° C. for 3 min to obtain the lithographic printing plate precursor (PP-h) having a total weight of the inner coating and outer coating of approximately 2.1 g/m².

The resulting planography printing plate precursor (PP-h) prepared in this example was subjected to scanning exposure by using 830 nm laser with a drum rotation speed of 220 rpm and a laser power of 12 W on a Kodak 800 Quantum-II type CTP platesetter. The exposed original plate was developed with Konita DV-T developer diluted with water at 25° C. for 35 s. After which, the coating on the exposed area of the resulting lithographic printing plate precursor was completely dissolved, while the coating on the unexposed area remained. The image was clear and the edges were sharp and neat.

1. An infrared radiation-sensitive positive-working imageable element, comprising:
(a) a substrate;
(b) an inner coating covering the substrate, the inner coating comprises a polymer binder P, which comprises at least two repeating units of a maleimide monomer and a (meth)acrylamide monomer and is soluble in an alkaline developing solution; and
(c) an outer coating covering the inner coating, the outer coating comprises an infrared radiation absorbing compound and a polymer binder Q which is different from the polymer binder Pinner coating.

2. The infrared radiation-sensitive positive-working imageable element of claim 1, wherein the polymer binder P comprised in the inner coating can be represented by the following structural formula (I):
—(A)ₓ-(B)_{y}-(C)_{z}— (I)
A represents a repeating unit derived from one or more maleimide monomers 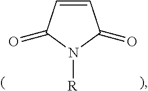
wherein R can be optionally substituted or unsubstituted alkyl, substituted or unsubstituted cycloalkyl, substituted or unsubstituted aryl, substituted or unsubstituted heteroaryl, hydroxyl, substituted or unsubstituted alkoxy; B represents a repeating unit derived from one or more (meth)acrylamide monomers 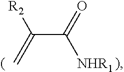
wherein R₁ can be optionally hydrogen, substituted or unsubstituted alkyl, substituted or unsubstituted cycloalkyl, substituted or unsubstituted aryl, substituted or unsubstituted heteroaryl, hydroxyl, substituted or unsubstituted alkoxy; R₂ can be optionally hydrogen or methyl; C represents a repeating unit derived from one or more other ethylenically unsaturated polymerizable monomers different from A and B; wherein, based on x+y+z=100% of a total weight of the polymer binder P having a structural formula (I), wherein x is 1 to 85 wt %, y is 1 to 80 wt %, and z is 1 to 80 wt %, or any combination thereof.

3. The infrared radiation-sensitive positive-working imageable element of claim 1, wherein the polymer binder P is 40-99.9wt % of the total weight of the inner coating.

4. The infrared radiation-sensitive positive-working imageable element of claim 1, wherein, the inner coating further comprises a background contrast dye, and the background contrast dye is a dye with high absorption in the visible light region, and the addition amount of the background contrast dye is 0.1 to 8 wt % of the total weight of the inner coating.

5. The infrared radiation-sensitive positive-working imageable element of claim 4, wherein the background contrast dye is one or a mixture of an oil-soluble dye and/or a basic dye.

6. The infrared radiation-sensitive positive-working imageable element of claim 1, wherein the inner coating further comprises an infrared radiation absorbing compound having a wavelength absorption range of 700 to1200 nm, and the addition amount of the infrared radiation absorbing compound is 0.1 to 10 wt % of the total weight of the inner coating.

7. The infrared radiation-sensitive positive-working imageable element of claim 6, wherein the infrared radiation absorbing compound is one or more of a cyanine dye, an anthraquinone dye, a phthalocyanine dye, a quinonimine dye or a methine cyanine dye.

8. The infrared radiation-sensitive positive-working imageable element of claim 1, wherein the inner coating further comprises an acid generator, and the addition amount of the acid generator is 0.1 to 10 wt % of the total weight of the inner coating.

9. The infrared radiation-sensitive positive-working imageable element of claim 8, wherein the acid generator is one or more of onium salt, triazine, acid anhydride and sulfonic ester.

10. The infrared radiation-sensitive positive-working imageable element of claim 1, wherein the inner coating further comprises a polymer binder P₁, the polymer binder P₁ is selected from one or more of phenolic resin, polystyrene derivative, polyurethane, and a polyacrylic acid (ester) which is different from the polymer binder P, and the addition amount of the polymer binder P₁ is 1 to 40 wt % of the total weight of the inner coating.

11. The infrared radiation-sensitive positive-working imageable element of claim 1, wherein the outer coating comprises an infrared radiation absorbing compound having a wavelength absorption range of 700 to 1200 nm and a polymer binder Q which is different from the polymer binder P, and the addition amount of the infrared radiation absorbing compound is 0.5 to 10 wt % of the total weight of the outer coating; the addition amount of the polymer binder Q is 80 to 99.5 wt % of the total weight of the outer coating.

12. The infrared radiation-sensitive positive-working imageable element of claim 11, wherein the infrared radiation absorbing compound is one or more of a cyanine dye, an anthraquinone dye, a phthalocyanine dye, a quinonimine dye or a methine cyanine dye.

13. The infrared radiation-sensitive positive-working imageable element of claim 11, wherein the polymer binder Q can be derived from one or more of phenolic resin, polystyrene derivative, polyurethane and polyacrylic acid which is different from the inner coating polymer binder P.

14. The infrared radiation-sensitive positive-working imageable element of claim 1, wherein the outer coating further comprises a dissolution inhibitor, wherein the dissolution inhibitor is one or more of a triarylmethane dye, an onium salt, a ketone or an ester compound, and the addition amount of the dissolution inhibitor is 0.1 to 20 wt % of the total weight of the outer coating.

15. The infrared radiation-sensitive positive-working imageable element of claim 1, wherein the outer coating further comprises an acid generator, the acid generator is selected from one or more of onium salt, triazine, acid anhydride, and sulfonate, and the addition amount of the acid generator is 0.2 to 10 wt % of the total weight of the outer coating.

16. The infrared radiation-sensitive positive-working imageable element of claim 1 is a positive-working lithographic printing plate precursor with a hydrophilic substrate, wherein the hydrophilic substrate is an aluminum substrate subjected to electrolytic roughening and anodizing treatment.

17. A method for forming an image, wherein the method comprising:
A) performing imagewise exposure of the imageable element of claim 1 with infrared radiation to form an imaged element comprising exposed and unexposed areas, B) contacting the imaged element with an alkaline developer to remove only the exposed area to produce an imaged and developed element.

18. The method for forming an image of claim 17, wherein the imagewise exposure is performed by an infrared laser with a radiation wavelength of 700-1200 nm, and the alkaline developer is an aqueous solution with a pH value of less than 14.

19. A lithographic printing plate obtained from the method of claim 17.

20. The infrared radiation-sensitive positive-working imageable element of claim 2 is a positive-working lithographic printing plate precursor with a hydrophilic substrate, wherein the hydrophilic substrate is an aluminum substrate subjected to electrolytic roughening and anodizing treatment.
